(19) United States
(12) Patent Application Publication
(10) Pub. No.: US 2018/0190541 A1
(43) Pub. Date: Jul. 5, 2018

(54) FAN-OUT LINE ARRANGEMENT, DISPLAY PANEL AND MANUFACTURING METHOD THEREOF

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventors: Shaozhuan WANG, Beijing (CN); Heecheol KIM, Beijing (CN)

(73) Assignees: BOE TECHNOLOGY GROUP CO., LTD., Beijing (CN); HEFEI XINSHENG OPTOELECTRONICS TECHNOLOGY CO., LTD., Beijing (CN)

(21) Appl. No.: 15/533,693

(22) PCT Filed: Jun. 30, 2016
(86) PCT No.: PCT/CN2016/087810

§ 371 Date: Jun. 7, 2017

(30) Foreign Application Priority Data
Mar. 29, 2016 (CN) 201610185117.0

(51) Int. Cl. H01L 21/768; H01L 23/528; H01L 23/522; H01L 21/3213

(52) U.S. Cl. CPC H01L 21/76892; H01L 21/32139; H01L 23/5228; H01L 23/528

(57) ABSTRACT

A fan-out line arrangement, a display panel and a manufacture method thereof are provided. The fan-out line arrangement provided by the present disclosure includes a plurality of fan-out lines having different lengths, wherein each of the fan-out lines includes a wiring layer; a supplementary conductive film is disposed on the wiring layer of each of at least some of the fan-out lines and electrically connected to the wiring layer; and the plurality of fan-out lines have the same impedance.

### CROSS-REFERENCE TO RELATED APPLICATIONS

The present application is based upon International Application No. PCT/CN2016/087810, filed on Jun. 30, 2016, which is based upon and claims priority to Chinese Patent Application No. 201610185117.0, filed Mar. 29, 2016, the entire contents of which are incorporated herein by reference.

### TECHNICAL FIELD

The present disclosure relates to the field of display technology, and more particularly, to a fan-out line arrangement, a display panel including the fan-out line arrangement and a manufacturing method thereof.

### BACKGROUND

A display panel includes a TFT array and a driving circuit module for driving the TFT array (such as a driving circuit board provided with a driving IC). In order to correspondingly apply an output signal of the driving circuit module to a corresponding signal line (e.g., a data line or a gate line) of the TFT array, a connecting wire is required to correspondingly connect a certain output pin of the driving circuit module to a certain signal line of the TFT array. According to a conventional driving circuit module and a conventional TFT array arrangement, a plurality of output pins of the driving circuit module are arranged to be relatively concentrated while a plurality of signal lines of the TFT array are arranged to be relatively distributed. Therefore, when a plurality of such connecting wires are employed, the connecting wires form a fan-like arrangement between the driving circuit module and the TFT array arrangement. Thus, the connecting wires are generally referred to as “fan-out lines”, and the region where the fan-out lines are disposed are referred to as a “fan-out area”.

However, distances from the output pins of the driver circuit module to the signal lines of the TFT array are inconsistent. This will inevitably result in large differences in the lengths of the fan-out lines, which thus tends to cause impedances of the plurality of fan-out lines in the fan-out area to be non-uniform. The non-uniformity of the impedances will affect display effect of the display panel and needs to be avoided as much as possible.

In the related art, in order to achieve uniform impedances between the different fan-out lines as much as possible, a fan-out line with a relatively short length is designed to be wound to increase its impedance. However, this method requires an additional area for the winding, and tends to increase the overall width of the fan-out area. The overall width of the fan-out area will be manifested on the bezel size of the display which employs the display panel. Therefore, the increase in the overall width of the fan-out area is not conducive to development and design of a display with a narrow bezel.

It should be noted that, information disclosed in the above background portion is provided only for better understanding of the background of the present disclosure, and thus it may contain information that does not form the prior art known by those skilled in the art.

### SUMMARY

The present disclosure provides the following technical solution.

According to one aspect of the present disclosure, a fan-out line arrangement is provided, including a plurality of fan-out lines having different lengths, wherein

Each of the fan-out lines includes a wiring layer;

a supplementary conductive film is disposed on the wiring layer of each of at least some of the fan-out lines and electrically connected to the wiring layer; and

the plurality of fan-out lines have the same impedance.

According to another aspect of the present disclosure, a display panel is provided, including a driving circuit module and a TFT array, and any one fan-out line arrangement described as above, wherein the fan-out line arrangement is configured to connect the driving circuit module with the TFT array.

According to yet another aspect of the present disclosure, a manufacturing method of a display panel is provided, including:

providing a substrate with a preset fan-out area;

forming a first conductive layer in the preset fan-out area by depositing;

forming a second conductive layer on a surface of the first conductive layer; and

forming a wiring layer and a supplementary conductive film by respectively etching the first conductive layer and the second conductive layer.

It is to be understood that both the foregoing general description and the following detailed description are exemplary and explanatory only and are not restrictive of the invention, as claimed.

This section provides a summary of various implementations or examples of the technology described in the disclosure, and is not a comprehensive disclosure of the full scope or all features of the disclosed technology.

### BRIEF DESCRIPTION OF THE DRAWINGS

In order to more clearly illustrate the technical solutions in embodiments of the present disclosure or in the related art, the following drawings to be used in the description of the embodiments or in the related art will be briefly introduced below. Apparently, the drawings in the following description are only for some embodiments of the disclosure, and those of ordinary skill in the art may also obtain other drawings from these drawings, without creative efforts.

FIG. 1 is a schematic diagram of a fan-out line arrangement according to an embodiment of the present disclosure.

FIG. 2 is a top view of a fan-out line of the fan-out line arrangement according to an embodiment of the present disclosure, and FIG. 3 is a cross sectional view of the fan-out line taken along A-A in the embodiment as shown in FIG. 2.

FIGS. 4 to 10 are flow charts illustrating a manufacturing method for manufacturing the fan-out line arrangement according to an embodiment of the present disclosure.

### DETAILED DESCRIPTION

Hereinafter, the technical solutions in the embodiments of the present disclosure will now be described clearly and fully in conjunction with the accompanying drawings in the embodiments of the present disclosure. Apparently, the described embodiments are merely part of the embodiments of the present disclosure and are not intended to be exhaustive. Based on the embodiments in the present disclosure, all other embodiments obtained by those of ordinary skill in the art without creative effort are within the scope of the present disclosure.

In the drawings, for the sake of clarity, a thickness of a layer and a region is exaggerated, and rounded shapes due to etching or other shape features are not shown in the drawings.

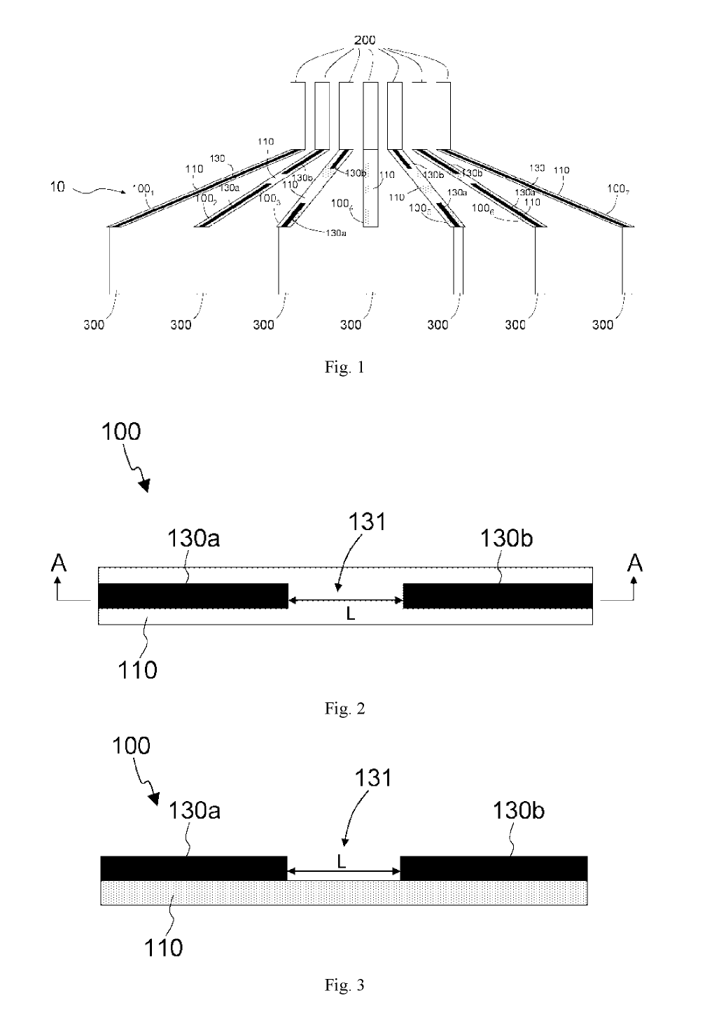

FIG. 1 is a schematic diagram of a fan-out line arrangement according to an embodiment of the present disclosure. In this embodiment, a fan-out line arrangement 10 is disposed in a fan-out area between a driving circuit module and a TFT array. The fan-out line arrangement 10 is configured to connect a plurality of pins 200 of a certain driving circuit module (such as a driving IC) correspondingly to a plurality of signal lines 300 of the TFT array, such that the driving circuit module can drive regions corresponding to the plurality of signal lines 300 of the TFT array, to implement display function. For illustration convenience, the example in FIG. 1 only shows the fan-out line arrangement including seven fan-out lines 100, i.e. fan-out lines 100₁, 100₂, 100₃, 100₄, 100₅, 100₆ and 100₇. The specific number of the fan-out lines 100 is not restrictive, and may be designed depending on the size of the TFT region required to be driven by the driving circuit module.

In this embodiment, the plurality of fan-out lines 100 have non-uniform lengths. For example, the length of the fan-out line 100₄ which is disposed in the middle is shortest, and the lengths of the other fan-out lines on either side of the fan-out line 100₄ increase successively. Thus, the lengths of the fan-out lines 100₅, 100₆ and 100₇ increase successively and the lengths of the fan-out lines 100₁, 100₂ and 100₃ also increase successively.

As shown in FIG. 1, each fan-out line 100 is provided with a wiring layer 110. The lengths of the wiring layers 110 respectively disposed on the plurality of fan-out lines 100₁, 100₂, 100₃, 100₄, 100₅, 100₆ and 100₇ are non-uniform, that is, the fan-out lines have different lengths. In an embodiment, the wiring layers 110 of the different fan-out lines 100 may be made of the same material, and they have substantially the same width and thickness. Thus, the impedances of the wiring layers of the different fan-out lines 100 having different lengths are different. In another embodiment, although the wiring layers 110 of the different fan-out lines 100 have different lengths, some of the wiring layers may also be respectively and specifically designed with different widths and thicknesses. For example, the shorter the length of the wiring layer is, the narrower the width of the wiring layer is designed, such that the wiring layers may have substantially the same impedance.

For the wiring layers 110 of at least some of the fan-out lines 100, a supplementary conductive film 130 is disposed on the wiring layer 110. The supplementary conductive film 130 is electrically conductive to the wiring layer 110. Thus, the overall fan-out line 100 is electrically conductive. The supplementary conductive film 130 has a lower resistivity than that of the wiring layer 110. Thus, in the segment of the wiring layer 110 where the supplementary conductive film 130 is disposed, its corresponding impedance may be reduced. The magnitude of the impedance reduction may be determined according to the conditions such as the length, width and/or thickness of the supplementary conductive film 130, and is particularly influenced by the length of the supplementary conductive film 130.

The supplementary conductive film 130 may be an uninterrupted segment, such as the supplementary conductive film 130 uninterruptedly disposed on the fan-out line 100₁ or 100₇. The supplementary conductive film 130 may also be disposed as separate segments, such as the supplementary conductive films 130a and 130b on the fan-out line 100₂, 100₃, 100₅ or 100₆, which are separate segments disposed on the wiring layer 110. Of course, for all of the fan-out lines 100 provided with the supplementary conductive film 130 in the fan-out line arrangement 10, it is possible that all of the supplementary conductive films 130 may be uninterruptedly disposed, or all of the supplementary conductive films 130 may be disposed as separate segments, or as shown in FIG. 1, some of the supplementary conductive films 130 may be uninterruptedly disposed, and others of them may be disposed as separate segments.

According to the resistance of the wiring layer 110 of each fan-out line 100, the length (the total length in case when multiple segments of supplementary conductive film 130a and 130b are disposed), width and/or thickness of the supplementary conductive film 130 of each fan-out line 100 may be determined, such that the impedances of the multiple fan-out lines 100₁, 100₂, 100₃, 100₄, 100₅, 100₆ and 100₇ are substantially the same. That is, the plurality of fan-out lines 100 of the fan-out line arrangement have substantially the equal impedance to each other. In an embodiment, for the plurality of fan-out lines 100 which is respectively provided with the supplementary conductive film 130, the supplementary conductive films 130 disposed on the wiring layers 110 having different lengths have different lengths. Thus, the impedances of the fan-out lines 100 having different lengths may be adjusted to be consistent.

Preferably, the impedances of the plurality of fan-out lines 100 are disposed as substantially the same as the impedance of the shortest fan-out line. That is, other fan-out lines are adjusted with reference to the impedance of the shortest fan-out line, such that they have substantially the same impedance as that of the shortest fan-out line 100₄. Thus, in an embodiment, the shortest fan-out line 100₄ may not be disposed with the supplementary conductive film 130, and each of the other fan-out lines 100₁, 100₂, 100₃, 100₅, 100₆ and 100₇ is disposed with the supplementary conductive film 130. That is, except for the shortest fan-out line 100₄, each of the wiring layers 110 of the plurality of fan-out lines is disposed with a supplementary conductive film 130 electrically connected to the wiring layer. Of course, in other embodiment, it is possible that the wiring layers 110 of the relatively short fan-out lines are not disposed with the supplementary conductive film 130, and for those relatively short fan-out lines, the widths of the wiring layers 110 having different lengths may be adjusted to make the impedances of those fan-out lines 100 to be consistent. Embodiments of the specific structure of the fan-out lines 100₁, 100₂, 100₃, 100₅, 100₆ and 100₇ disposed with the supplementary conductive film 130 are described below.

However, it should be noted that, in other embodiment, the supplementary conductive film 130 may be disposed on the shortest fan-out line 100₄ to reduce the impedance of the shortest fan-out line 100₄, such that the impedance of each fan-out line of the fan-out line arrangement 100 is further consistently reduced. Thus, the wiring layers of all of the fan-out lines of the fan-out line arrangement are disposed with the supplementary conductive film.

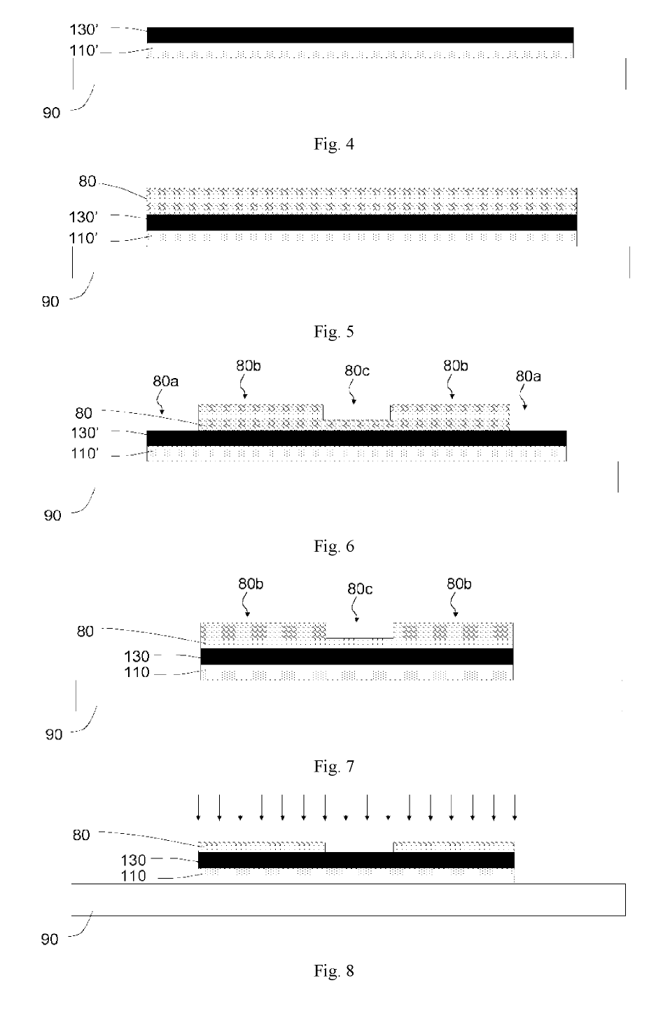

FIG. 2 is a top view of a fan-out line of the fan-out line arrangement according to an embodiment of the present disclosure, and FIG. 3 is a cross sectional view of the fan-out line taken along A-A in the embodiments as shown in FIG. 2.

In FIG. 2 in conjunction with FIG. 3, the fan-out line 100 is electrically conductive as a whole, and may be configured to conduct a driving signal from the driving circuit module to a signal line of the TFT array. The fan-out line 100 includes a wiring layer 110 and a supplementary conductive film 130 stacked on the wiring layer 110. The resistivity of the wiring layer 110 is larger than the resistivity of the supplementary conductive film 130. For example, the wiring layer 110 may be an ITO wiring made of ITO (indium tin oxide) material having a relatively high resistivity. The supplementary conductive film 130 may be a metal wiring made of metal material (such as aluminum and so on) having a relatively low resistivity. In an embodiment, the resistivity of the wiring layer 110 may be more than 10 times of the resistivity of the supplementary conductive film 130, such as 100 times. Thus, when there are both of the wiring layer 110 and the supplementary conductive film 130, the supplementary conductive film 130 is mainly used for electricity conduction. Therefore, the supplementary conductive film 130 may be understood as a conductive function layer. Specifically, the wiring direction of the wiring layer 110 is substantially the same as the wiring direction of the supplementary conductive film 130. It should be noted that, the case of the supplementary conductive film 130 being embedded in the surface of the wiring layer 110 may be understood as the conductive film 130 being disposed on the wiring layer 110

Still referring to FIGS. 2 and 3, for the supplementary conductive film 130 which is disposed as separate segments, a segment between the supplementary conductive film 130a and the supplementary conductive film 130b is a segment 131 without a supplementary conductive film. Moreover, at a segment corresponding to the segment 131 without a supplementary conductive film, electricity cannot be conducted between the supplementary conductive film 130a and the supplementary conductive film 130b through the supplementary conductive film 130a and the supplementary conductive film 130b themselves, which is conducted by means of a portion of the wiring layer 110 which corresponds to the segment 131. When the segment 131 without a supplementary conductive film has a length L, since the resistance of the wiring layer 110 having a length L is significantly larger than the resistance of the supplementary conductive film 130 having a length L, the impedance of the portion of the fan-out line which corresponds to the segment 131 is significantly increased, and the resistance of the fan-out line 10 is also increased.

It should be noted that, the segment without a supplementary conductive film may also exist in case where the supplementary conductive film is uninterruptedly disposed. For example, when the supplementary conductive film 130a is bonded with the supplementary conductive film 130b, a region outside of the supplementary conductive films is a segment without a supplementary conductive film.

When the fan-out line 100 is conducted with electricity in operation, the segments corresponding to the supplementary conductive film 130a and the supplementary conductive film 130b mainly conduct electricity through the supplementary conductive film 130a and the supplementary conductive film 130b (since they have relatively low resistivity), while the segment 131 without a supplementary conductive film conducts electricity completely through the wiring layer 110. When the length L of the segment 131 varies, the resistance of the wiring layer 110 corresponding to the segment 131 also varies. Therefore, the magnitude of the resistance or impedance of the entire fan-out line 100 also varies. The longer the length L of the segment 131 without a supplementary conductive film is, the larger the impedance of the fan-out line 100 is.

In an embodiment, the width of the wiring layer 110 is larger than the width of the supplementary conductive film 130 (as shown in FIG. 1). In another alternative embodiment, the width of the wiring layer 110 may be substantially the same as the width of the supplementary conductive film 130. Segments of a supplementary conductive film 130a and a supplementary conductive film 130b on the same wiring layer 110 may have the same thickness and the same width. Supplementary conductive films 130 on different wiring layers 110 may also have the same thickness and the same width.

In another embodiment, the supplementary conductive film 130 may be made of the same material as that of the wiring layer 110. Thus, the segment correspondingly provided with the supplementary conductive film 130 has its conductive cross sectional area (the sum of the cross sectional areas of the supplementary conductive film 130 and the wiring layer 110) increased, so its corresponding impedance decreases, such that the impedance of the fan-out line 100 may also be adjusted by changing the length, width and/or height of the supplementary conductive film 130.

The fan-out line arrangement in the above embodiments may achieve uniform and consistent impedances. Therefore, when such fan-out line arrangement is applied to form a display panel, the display effect may be improved. Moreover, the fan-out lines in such fan-out line arrangement do not employ windings, and thus need not to additionally increase the width of the fan-out area that is required by the fan-out line arrangement. Therefore, it is suitable to be applied to a display with a narrow bezel.

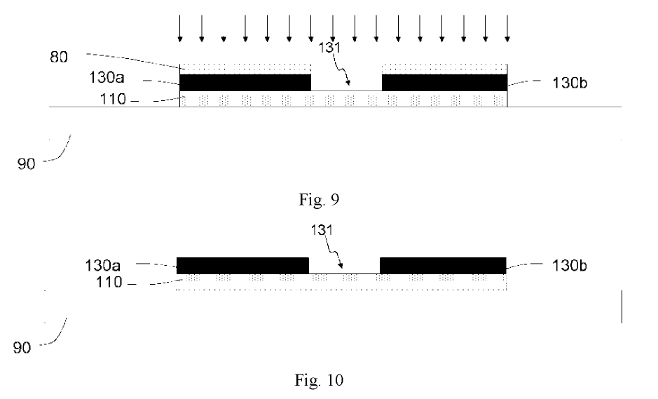

FIGS. 4 to 10 are flow charts illustrating a fabrication method for fabricating the fan-out line arrangement according to an embodiment of the present disclosure. Hereinafter, the process for fabricating the fan-out line arrangement of the embodiment as shown in FIG. 1 will be illustrated with reference to FIGS. 4 to 10, in which one fan-out line is shown as an example for illustration. It should be understood that when the lengths L of the segments without a supplementary conductive film of other fan-out lines are determined, the other fan-out lines may also be formed at the same time.

Firstly, as shown in FIG. 4, a first conductive layer 110′ is deposited and formed on a glass substrate 90, and patterned to form a wiring layer 110. Then, a second conductive layer 130′ is deposited and formed on the first conductive layer 110′, and patterned to form a supplementary conductive film 130. The thicknesses of the first conductive layer 110′ and the second conductive layer 130′ may be determined respectively according to the desired thicknesses of the wiring layer 110 and the supplementary conductive film 130 to be formed. Specifically, the first conductive layer 110′ may be but not limited to an ITO layer, and the second conductive layer 130′ may be but not limited to a metal layer.

Further, as shown in FIG. 5, the second conductive layer 130′ is coated with a photoresist 80.

Further, as shown in FIG. 6, the photoresist 80 is exposed by a half tone mask and then developed to remove the adhesive to form a region 80b where the photoresist is completely preserved, a region 80c where the photoresist is half preserved and a region 80a where the photoresist is completely removed. The above region 80b where the photoresist is completely preserved, the region 80c where the photoresist is half preserved and the region 80a where the photoresist is completely removed are defined relative to the photoresist 80 in FIG. 5. The region 80c where the photoresist is half preserved is at least used to correspondingly form the segment without a supplementary conductive film, and may be defined according to the segment without a supplementary conductive film desired to be formed.

Further, as shown in FIG. 7, etching is performed using the photoresist 80 as a mask. That is, the first conductive layer 110′ and the supplementary conductive film 130 are etched with the photoresist in the region where the photoresist is completely preserved and the region where the photoresist is half preserved as a mask, such that an arrangement of a plurality of fan-out lines including double layers of wiring (the supplementary conductive film 130 is uninterrupted at this time) is formed on the glass substrate 90. The etching can be performed by wet etching followed by cleaning.

Further, as shown in FIG. 8, the photoresist 80 in the region where the photoresist is completely preserved and the region where the photoresist is half preserved are subjected to an ashing process simultaneously. Since the thicknesses of the region where the photoresist is completely preserved and the region where the photoresist is half preserved are not consistent, the photoresist in the thinner region where the photoresist is half preserved is firstly removed by the ashing treatment, so as to expose portion of the wiring layer 130 corresponding to the region where the photoresist is half preserved. After the photoresist where the photoresist is half preserved is removed by ashing, the ashing process is finished, such that the photoresist 80 will be left correspondingly in the region where the photoresist is completely preserved on the wiring layer 130, and such photoresist 80 will be used as a mask in subsequent etching process. The thickness of the region where the photoresist is completely preserved is larger than the thickness of the region where the photoresist is half preserved. Specifically, the thickness of the region where the photoresist is completely preserved is ½ of the thickness of the region where the photoresist is half preserved.

Further, as shown in FIG. 9, the exposed portion of the supplementary conductive film 130 is etched to form separate segments of supplementary conductive films 130a and 130b for each fan-out line. At the same time, the segment 131 without a supplementary conductive film is also formed. In this step, the photoresist 80 functions as a mask layer, to protect the supplementary conductive films 130a and 130b which are desired to be preserved. The etching can be performed by wet etching followed by cleaning. During the process of etching the exposed portion of the supplementary conductive film 130, the etching is selectively performed on the portion of the supplementary conductive film 130, but not on the wiring layer 10, and specifically implemented by means of selective etching solution and so on.

Further, as shown in FIG. 10, the photoresist 80 is removed, cleaned, to fabricate and form a fan-out line arrangement including a plurality of fan-out lines as shown in FIG. 1.

During the above fabrication method of the fan-out line arrangement in the display panel, only a half tone mask, one exposure process, one ashing process and two etching processes are needed for the fabrication. The fabrication process is simple and the cost is low. Based on the above fabrication method of the fan-out line arrangement, a corresponding display panel may be fabricated.

It should be understood that, the fabrication method of the fan-out line arrangement does not limited to the above embodiment. In other embodiment, more than one masks and more than one exposure processes may also be employed for the fabrication. For example, the double layers of fan-out line arrangement is formed with one mask and performed with one exposure process, and the segment without supplementary conductive film is formed with another mask and performed with another exposure process, which is relatively complex in processes.

The present disclosure also provides a display panel example based on the formation of the fan-out line arrangement embodiment as shown in FIG. 1, including a driving circuit module, a TFT array, and a fan-out line arrangement between the driving circuit module and the TFT array. The display panel has excellent display effect.

It should be noted that, in the above embodiments, the supplementary conductive film 130 on the wiring layer 110 of the fan-out line 100 may also be separated to three or more segments, and the specific separation is not limited. By controlling the total length of the supplementary conductive film 130, the total length of the segment without supplementary conductive film may be controlled, and thus the impedance of each fan-out line 100 may be set.

The above example mainly describes the fan-out line arrangement, the fabrication method of the fan-out line arrangement and the display panel which can apply the fan-out line arrangement of the present disclosure. Although only some of the embodiments of the present disclosure are described, it should be understood by those skilled in the art that the present disclosure may be practiced in many other forms without departing from the spirit and scope thereof. Accordingly, the illustrated examples and embodiments are to be considered as illustrative and not restrictive, and that the present disclosure may include various modifications and alternatives without departing from the spirit and scope of the present disclosure as defined by the appended claims. The above is only specific embodiments of the present disclosure, and the protection scope of the present disclosure is not limited thereto. All of the modifications or alternatives readily apparent to those skilled in the art within the technical scope of the present disclosure should be covered in the protection scope of the present disclosure. Accordingly, the protection scope of the present disclosure should be based on the protection scope of the claims.

1. A fan-out line arrangement, comprising a plurality of fan-out lines having different lengths, wherein
each of the fan-out lines comprises a wiring layer;
a supplementary conductive film is disposed on the wiring layer of each of at least some of the fan-out lines and is electrically connected to the wiring layer; and
the plurality of fan-out lines have the same impedance.

2. The fan-out line arrangement of claim 1, wherein the wiring layers having different lengths have different impedances.

3. The fan-out line arrangement of claim 2, wherein among the plurality of fan-out lines, except for the wiring layer having the shortest length, the supplementary conductive film is disposed on the wiring layer of each of the remaining fan-out lines and electrically connected to the wiring layer.

4. The fan-out line arrangement of claim 2, wherein among the plurality of fan-out lines, the supplementary conductive film is disposed on the wiring layer of each of the fan-out lines and is electrically connected to the wiring layer.

5. The fan-out line arrangement of claim 3, wherein the supplementary conductive film disposed on a wiring layer of one of the fan-out lines and the supplementary conductive film disposed on a wiring layer of another of the fan-out lines have the same thickness and the same width.

6. The fan-out line arrangement of claim 2, wherein among the plurality of fan-out lines disposed with the supplementary conductive films, the supplementary conductive films respectively disposed on the wiring layers having different lengths have different lengths.

7. The fan-out line arrangement of claim 1, wherein the supplementary conductive film is uninterruptedly disposed on the wiring layer, or is disposed on the wiring layer as separate segments.

8. The fan-out line arrangement of claim 1, wherein the supplementary conductive film is made of the same material as that of the wiring layer.

9. The fan-out line arrangement of claim 1, wherein the supplementary conductive film is made of different material from that of the wiring layer, and the material of the supplementary conductive film has a resistivity smaller than that of the material of the wiring layer.

10. A display panel, comprising a driving circuit module and a TFT array, and the fan-out line arrangement of claim 1, wherein the fan-out line arrangement is configured to connect the driving circuit module with the TFT array.

11. A manufacturing method of a display panel, comprising:
providing a substrate with a preset fan-out area;
forming a first conductive layer in the preset fan-out area by depositing;
forming a second conductive layer on a surface of the first conductive layer; and
forming a wiring layer and a supplementary conductive film by respectively etching the first conductive layer and the second conductive layer.

12. The manufacturing method of claim 11, wherein forming the wiring layer and the supplementary conductive film by respectively etching the first conductive layer and the second conductive layer comprises:
coating a photoresist on the second conductive layer;
exposing and developing the photoresist with a half tone mask, to form a region where the photoresist is completely preserved, a region where the photoresist is half preserved and a region where the photoresist is completely removed;
etching the first conductive layer and the second conductive layer with the region where the photoresist is completely preserved and the region where the photoresist is half preserved as masks, to form a plurality of wiring layers;
performing an ashing process simultaneously on the region where the photoresist is completely preserved and the region where the photoresist is half preserved to expose a portion of the second conductive layer corresponding to the region where the photoresist is half preserved;
etching the exposed portion of the second conductive layer to form a supplementary conductive film; and removing the remaining photoresist.

13. The fan-out line arrangement of claim 4, wherein the supplementary conductive film disposed on a wiring layer of one of the fan-out lines and the supplementary conductive film disposed on a wiring layer of another of the fan-out lines have the same thickness and the same width.
